(19) United States
(12) Patent Application Publication
(10) Pub. No.: US 2009/0179143 A1
(43) Pub. Date: Jul. 16, 2009

(54) IMAGE CAPTURING DEVICE

(75) Inventors: Takashi MUROOKA, Ashigarakami-gun (JP); Hideyasu ISHIBASHI, Ashigarakami-gun (JP); Ichiro AMIMORI, Minamiashigara-shi (JP)

Correspondence Address: SUGHRUE MION, PLLC, 2100 PENNSYLVANIA AVENUE, N.W., SUITE 800, WASHINGTON, DC, 20037, US

(73) Assignee: FUJIFILM CORPORATION, Tokyo (JP)

(21) Appl. No.: 12/355,370

(22) Filed: Jan. 16, 2009

(30) Foreign Application Priority Data
Jan. 16, 2008 (JP) 2008-007022

(51) Int. Cl. H01L 31/0232

(52) U.S. Cl. 250/225; 250/227.2

(57) ABSTRACT

An image capturing device includes a lens system including a plurality of regions on a pupil plane that each have different focal distances, a plurality of first polarizing elements that respectively transmit differently polarized light and respectively transmit light passing through the plurality of regions, a plurality of second polarizing elements that respectively transmit polarized light transmitted through the plurality of first polarizing elements, and a plurality of light receiving elements that respectively receive light transmitted through the plurality of second polarizing elements.

### CROSS REFERENCE TO RELATED APPLICATION

This patent application claims priority from a Japanese patent application No. 2008-007022 filed on Jan. 16, 2008, the contents of which are incorporated herein by reference.

### BACKGROUND

1. Field of the Invention

The present invention relates to an image capturing device. More particularly, the present invention relates to an image capturing device including polarizers and an optical system.

2. Related Art

A microscope that includes an optical system providing a lens group including two double focus lenses in at least one of an objective lens and an imaging lens and a polarizing plate placed at an imaging position of the optical system has been known, and the microscope can observe an image formed by placing beams transmitted through the polarizing plate at an appropriate position by means of an imaging lens. See, for example, Japanese Patent Application Publication No. 1999-271628. Moreover, there has been known a technique for capturing an image obtained by a double-focus optical system, which uses quartz crystal that is birefringent crystal as glass materials, by changing focal positions of the double-focus optical system through the rotation of the polarization direction of light transmitted through the polarizing plate by means of the change of orientation of liquid crystal by a liquid crystal device. See, for example, Japanese Patent Application Publication No. 1999-32251.

According to the technique described in Japanese Patent Application Publication No. 1999-271628, high magnification and low magnification observation can be simultaneously performed, but a subject image easily becomes dim when a distance to a subject changes. According to an invention described in Japanese Patent Application Publication No. 1999-32251, it is not possible to take in one shot a clear image for two subjects that are placed at different distances.

### SUMMARY

Therefore, it is an object of one aspect of innovation included in the present specification to provide an image capturing device that can solve the foregoing problems. The above and other objects can be achieved by combinations described in the independent claims. The dependent claims define further advantageous and exemplary combinations of the present invention.

According to an aspect of innovation included in the present specification, there is provided an image capturing device. The image capturing device includes: a lens system including a plurality of regions on a pupil plane that each have different focal distances; a plurality of first polarizing elements that respectively transmit differently polarized light and respectively transmit light passing through the plurality of regions; a plurality of second polarizing elements that respectively transmit polarized light transmitted through the plurality of first polarizing elements; and a plurality of light receiving elements that respectively receive light transmitted through the plurality of second polarizing elements.

According to another aspect of innovation included in the present specification, there is provided an optical system. The optical system includes: a lens system including a plurality of regions on a pupil plane that each have different focal distances; a plurality of first polarizing elements that respectively transmit differently polarized light and respectively transmit light passing through the plurality of regions; and a plurality of second polarizing elements that respectively transmit polarized light transmitted through the plurality of first polarizing elements.

The summary clause does not necessarily describe all necessary features of the embodiments of the present invention. The present invention may also be a sub-combination of the features described above. The above and other features and advantages of the present invention will become more apparent from the following description of the embodiments taken in conjunction with the accompanying drawings.

### BRIEF DESCRIPTION OF THE DRAWINGS

FIG. 1 is a view exemplary showing a configuration of an image capturing apparatus 10 according to an embodiment.

FIG. 2 is a view exemplary showing a configuration of a polarizing plate 135.

FIG. 3 is a view exemplary showing a configuration of an analyzer array 145 and a light receiving element array 150.

FIG. 4 is a view showing another configuration example of the polarizing plate 135.

FIG. 5 is a view showing further another configuration example of the polarizing plate 135.

FIG. 6 is a view showing another configuration example of the image capturing apparatus 10.

### DESCRIPTION OF EXEMPLARY EMBODIMENTS

The embodiments of the invention will now be described based on the preferred embodiments, which do not intend to limit the scope of the present invention, but just exemplify the invention. All of the features and the combinations thereof described in the embodiment are not necessarily essential to the invention.

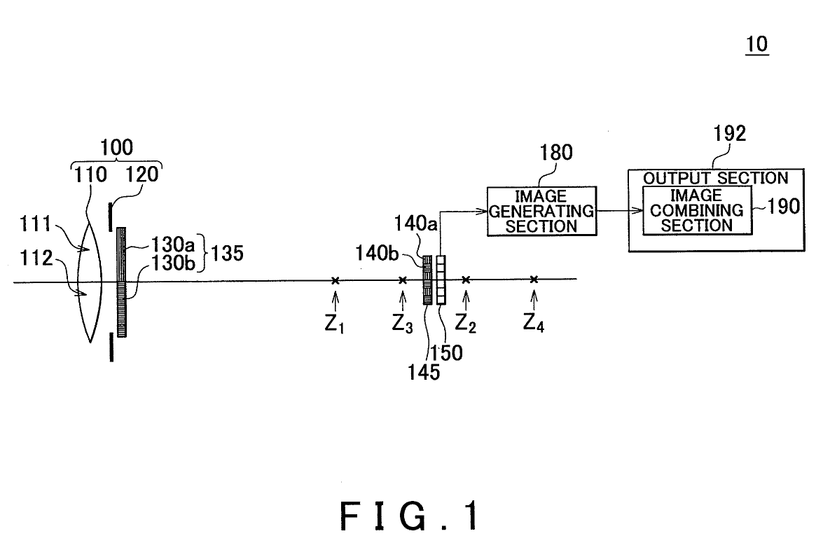

FIG. 1 shows an example of a configuration of an image capturing apparatus 10 according to an embodiment. The image capturing apparatus 10 includes a lens system 100 including a lens 110 and a diaphragm 120, a polarizing plate 135, an analyzer array 145, and a light receiving element array 150.

In the lens 110, a partial region 111 and a partial region 112 have different focal distances. For example, in the lens 110, the partial region 111 and the partial region 112 may have different refractive index. In addition, in the lens 110, the partial region 111 and the partial region 112 may have different shapes. In this manner, in the lens 110, the partial region 111 and the partial region 112 have different optical characteristics, in order to place light passing through the partial region 111 and light passing through the partial region 112 at different positions on the lens. Furthermore, the lens 110 may be a lens system having a plurality of lenses.

The diaphragm 120 narrows down light passing through the lens 110. The light passing through the diaphragm 120 is incident on the polarizing plate 135. The polarizing plate 135 is provided in the vicinity of the diaphragm 120, and has a plurality of polarizers 130a and 130b (hereinafter, these polarizers may be referred to as a polarizer 130) as an example of a plurality of first polarizing elements that transmit differently polarized light. The plurality of polarizers 130 have a transmission axis substantially perpendicular to each other, and transmit light polarized in polarization directions substantially perpendicular to each other.

The polarizer 130a is provided at a position through which light passing through the partial region 111 of the lens 110 and the diaphragm 120 passes. The polarizer 130a transmits light polarized in a specific transmission-axis direction of the polarizer 130a among light passing through the partial region 111 of the lens 110 and the diaphragm 120. Moreover, the polarizer 130b is provided at a position through which light passing through the partial region 112 of the lens 110 and the diaphragm 120 passes. The polarizer 130b transmits light polarized in a specific transmission-axis direction of the polarizer 130b among light passing through the partial region 112 of the lens 110 and the diaphragm 120. In this manner, the polarizing plate 135 transmits light having specific polarization directions that are substantially perpendicular to each other.

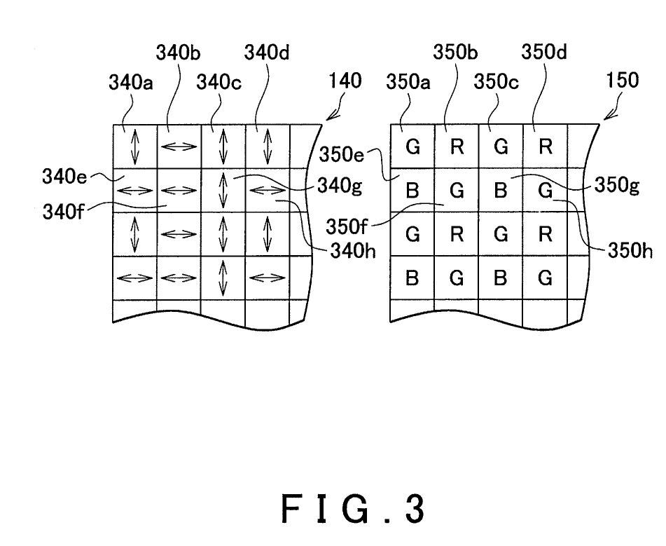

The light transmitted through the polarizing plate 135 is incident on the analyzer array 145. The analyzer array 145 has a plurality of analyzers 140a and 140b (hereinafter, these analyzers may be referred to as an analyzer 140) as an example of a plurality of second polarizing elements which each transmit polarized light transmitted through the plurality of first polarizing elements. The analyzers 140a and 140b each transmit light polarized in polarization directions of the polarizer 130a and the polarizer 130b. Specifically, the analyzer array 145 has the plurality of analyzers 140a that transmit light polarized in a direction transmitted through the polarizer 130a and the plurality of analyzers 140b that transmit light polarized in a direction transmitted through the polarizer 130b. In addition, the configuration of the analyzer of the analyzer array 145 further will be described with reference to FIG. 3.

The light transmitted through the analyzer array 145 is incident on, as an example, the light receiving element array 150 that is provided in the vicinity of the analyzer array 145. The light receiving element array 150 has a plurality of light receiving elements that each receive light transmitted through the plurality of analyzers included in the analyzer array 145. The light receiving element array 150 receives, through different light receiving elements, light polarized in the transmission-axis direction of the polarizer 130a, which is transmitted through the analyzer included in the analyzer array 145, and light polarized in the transmission-axis direction of the polarizer 130b. In this manner, the light receiving element array 150 receives, through different light receiving elements, light passing through the partial region 111 and light passing through the partial region 112. In addition, the configuration of the light receiving element of the light receiving element array 150 will be further described with reference to FIG. 3.

The image generating section 180 generates a first image from the light receiving element which receives light passing through the partial region 111. Moreover, the image generating section 180 generates a second image from the light receiving element which receives light passing through the partial region 112. Then, the output section 192 performs image processing on either the first image or the second image and outputs the result.

Hereinafter, image capturing characteristics of the image capturing apparatus 10 will be easily described using the case that light from an object point on the optical axis of the lens system 100 is incident on the lens system 100 as an example. The light from the object point, which is incident on the lens 110 and passes through the partial region 111 of the lens 110, forms an image at a position z1 in an optical axis direction. Moreover, light passing through the partial region 112 of the lens 110 among light from the object point forms an image at a position z2 on the optical axis.

Here, it is assumed that the light receiving element array 150 is provided at the position closer to the position z2 than the position z1. In this case, the second image is obtained by signals received from a light receiving element that receives light passing through the partial region 112 of the lens 110, that is to say, light polarized in the transmission-axis direction of the polarizer 130b, among light from a subject at the same subject distance as the object point. The second image includes a clearer subject image than that of the first image which is generated by signals from another light receiving element. In this case, the output section 192 may select the second image having a clearer subject image and output the selected image among the first image and the second image generated from the image generating section 180.

In addition, light passing through the partial region 111 of the lens 110 forms an image at a position z3 in an optical axis direction, among light from another object point closer to the lens system 100 than the object point as described above on the optical axis of the lens 110. Moreover, among light from the other object point, light passing through the partial region 112 of the lens 110 forms an image at a position z4 in the optical axis direction.

Here, it is assumed that the light receiving element array 150 is provided in the position closer to the position z3 than position the z4. In this case, the first image is generated by signals received from a light receiving element that receives light passing through the partial region 111 of the lens 110, that is to say, light polarized in the transmission-axis direction of the polarizer 130a, among light from a subject at the same subject distance as the other object point. The first image includes a clearer subject image than that of the second image which is generated by signals from another light receiving element.

In addition, the output section 192 may preferentially output a clearer image among the first image and the second image. According to this, although a distance to a subject changes to some extent, a clear subject image can be obtained. Moreover, when the light receiving element array 150 exists in the vicinity of the position z2 and the position z3, the focused image of the subject at the same subject distance as the two object points can be obtained in one shot.

In addition, the image combining section 190 may output a composite image obtained by providing weights to the first image and the second image and combining the weight images. In this case, a composite image obtained by focusing the image capturing apparatus on both sides of a subject located at a short distance and a subject located at a long distance can be obtained. In this manner, according to the image capturing apparatus 10 of the present embodiment, it is possible to take a subject with deep depth of field.

In the above descriptions, there have been described an operation and a function of the image capturing apparatus 10 by means of the configuration of the image capturing apparatus 10 in which substantially perpendicular linearly-polarized light is utilized. However, the image capturing apparatus 10 can achieve the same function as that of the above configuration by the same operation of that of the above configuration even when utilizing polarized light substantially perpendicular to each other, such as clockwise circularly-polarized light and anticlockwise circularly-polarized light, in addition to linearly-polarized light substantially perpendicular to each other. In other words, it is preferable that the first polarizing element in the present invention each transmit polarized light substantially perpendicular to each other. In addition, the polarized light substantially perpendicular to each other may be polarized light expressed with two points that are symmetric about an original point on a Poincare sphere when expressing polarization with a Poincare sphere like the substantially perpendicular linearly-polarized light, clockwise circularly-polarized light, anticlockwise circularly-polarized light, and so on as described above.

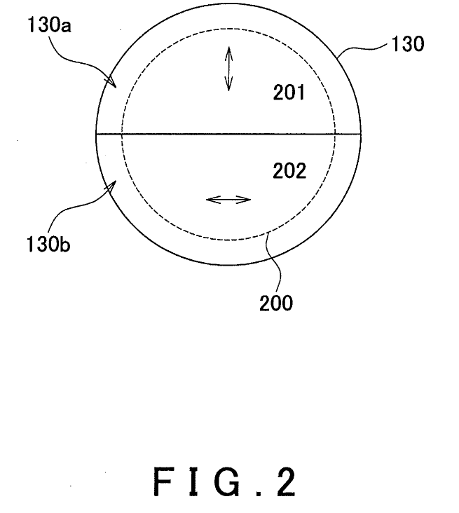

FIG. 2 shows an example of the configuration of the polarizing plate 135. FIG. 2 shows a cross section of the polarizing plate 135 perpendicular to the optical axis of the lens system 100. The first polarizer 130a and the second polarizer 130b have semicircular shapes that are in contact with each other on a border line including a point intersecting with the optical axis. As described above, a transmission axis of the polarizer 130a and a transmission axis of the polarizer 130b are perpendicular to each other. In this manner, the polarizer 130a and the polarizer 130b transmit light having polarization directions different from each other.

In addition, in FIG. 2, light passing through a region 201 and a region 202 on a pupil plane 200 is incident on regions on the polarizing plate 135 which have the same reference numbers as those of the ranges on the pupil plane. In addition, the light passing through the partial region 111 of the lens 110 passes through the region 201 on the pupil plane 200. The light passing through the partial region 112 of the lens 110 passes through the region 202 on the pupil plane 200.

In other words, the light passing through the region 201 on the pupil plane 200 passes through the partial region 111 of the lens 110 and the polarizer 130a. Moreover, the light passing through region 202 on the pupil plane passes through the partial region 112 of the lens 110 and the polarizer 130b. In this manner, the lens system 100 has different focal distances for the plurality of regions on the pupil plane 200, and the plurality of polarizers 130 each transmit light passing through the plurality of regions.

In addition, it is preferred that an amount of light passing through the partial region 111 of the lens 110 and then passing through the polarizer 130a at least be larger than that of light passing through the partial region 111 of the lens 110 and then passing through the polarizer 130b. Moreover, it is preferred that an amount of light passing through the partial region 112 of the lens 110 and then passing through the polarizer 130b at least be larger than that of light passing through the partial region 112 of the lens 110 and then passing through the polarizer 130a.

Therefore, it is preferred that the polarizer 130 of the polarizing plate 135 be provided at a position closer to a subject than any focal points (specifically, posterior focal points) of the lens system 100 on the optical axis of the lens system 100. The polarizer 130 of the polarizing plate 135 may be provided at a position closer to the subject than to the lens system 100. As an example, it is preferred that the polarizer 130 of the polarizing plate 135 be provided on the pupil plane of the lens system 100 or in the vicinity of the pupil plane. In addition, it goes without saying that it is preferred that the light passing through the partial region 111 of the lens 110 do not pass through the polarizer 130b and the light passing through the partial region 112 of the lens 110 do not pass through the polarizer 130a.

FIG. 3 shows an example of the configuration of the analyzer array 145 and the light receiving element array 150. FIG. 3 shows a section cross, of the analyzer array 145 and the light receiving element array 150, perpendicular to the optical axis of the lens system 100. The analyzer array 145 includes a plurality of analyzers 340a to 340h (hereinafter, these analyzers may be referred to as an analyzer 340).

The analyzer array 145 is formed by arranging the analyzers 340 in a matrix. In addition, the analyzers 340 arranged in a matrix are typically illustrated as the analyzer 140 in FIG. 1. The analyzer 340a, the analyzer 340c, the analyzer 340d, and the analyzer 340g have a transmission axis in the same direction as that of the transmission axis of the polarizer 130a. Moreover, the analyzer 340b, the analyzer 340e, the analyzer 340f, and the analyzer 340h have a transmission axis in the same direction as that of the transmission axis of the polarizer 130b.

The light receiving element array 150 has light receiving elements 350a to 350f (hereinafter, these elements maybe referred to as a light receiving element 350). The light receiving element 350a, the light receiving element 350c, the light receiving element 350f, and the light receiving element 350h receive light having a green wavelength region. The light receiving element 350b and the light receiving element 350d receive light having a red wavelength region. The light receiving element 350e and the light receiving element 350g receive light having a blue wavelength region.

In addition, the light receiving elements 350a, 350b, 350c, 350d, 350e, 350f, 350g, and 350h each receive light transmitted through the analyzers 340a, 340b, 340c, 340d, 340e, 340f, 340g, and 340h. Therefore, the light receiving element 350a and the light receiving element 350c receive green light polarized in the direction of the transmission axis of the polarizer 130a. Moreover, the light receiving element 350d receives red light polarized in the direction of the transmission axis of the polarizer 130a. The light receiving element 350g receives blue light polarized in the direction of the transmission axis of the polarizer 130a.

Moreover, the light receiving element 350b receives red light polarized in the direction of the transmission axis of the polarizer 130b. The light receiving element 350e receives blue light polarized in the direction of the transmission axis of the polarizer 130b. In addition, the light receiving element 350f and the light receiving element 350h receive green light polarized in the direction of the transmission axis of the polarizer 130b.

The image generating section 180 generates the first image on the basis of signals from the light receiving element 350 that can receive light polarized in the same direction as that of the transmission axis of the polarizer 130a. Specifically, the image generating section 180 generates RGB information for one pixel at least on the basis of G signals from the light receiving element 350a and the light receiving element 350c, R signals from the light receiving element 350d, B signals from the light receiving element 350g. Moreover, the image generating section 180 generates the second image on the basis of signals from the light receiving element 350 that can receive light polarized in the same direction as that of the transmission axis of the polarizer 130b. For example, the image generating section 180 generates RGB information for one pixel at least on the basis of G signals from the light receiving element 350f and the light receiving element 350h, R signals from the light receiving element 350b, and B signals from the light receiving element 350e.

In this manner, the light receiving element array 150 is formed by arranging the light receiving elements 350 in a matrix. The analyzers 340 are respectively arranged in a matrix in front of the light receiving elements 350. In addition, it is preferred that the light receiving elements 350 be provided between the plurality of focal points of the lens system 100. For example, it is preferred that the light receiving element array 150 be provided between the focal position of the partial region 111 of the lens system 100 and the focal position of the partial region 112 of the lens system 100.

Moreover, as described above, the image generating section 180 respectively generates images by means of light having different polarization directions received by the light receiving elements 350. The output section 192 preferentially outputs an image having the best picture quality as a captured image among the plurality of images generated from the image generating section 180. Moreover, the image combining section 190 may generate a composite image made by combining the plurality of images generated from the image generating section 180. At this time, the image combining section 190 may generate a composite image by providing a larger weight to an image having higher picture quality and combining the weighted images among the plurality of images generated from the image generating section 180.

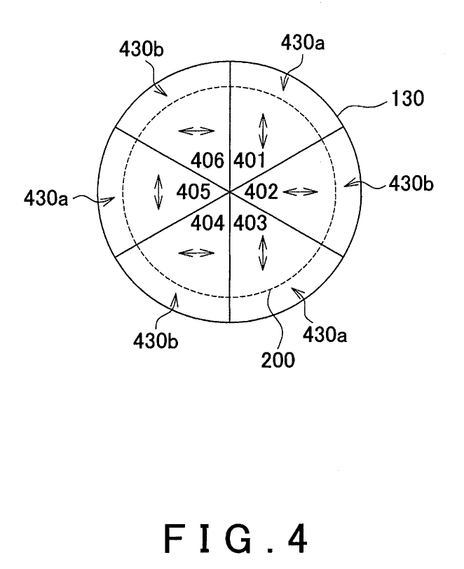

FIG. 4 shows another configuration example of the polarizing plate 135. FIG. 4 shows a cross section, of the polarizing plate 135, perpendicular to the optical axis of the lens system 100.

A plurality of polarizers 430a (hereinafter, referred to as a polarizer 430a) and a plurality of polarizers 430b (hereinafter, referred to as a polarizer 430b) have sector forms divided by a plurality of border lines including a point intersecting with the optical axis. Moreover, the transmission axis of the polarizer 430a is perpendicular to the transmission axis of the polarizer 430b.

In addition, in FIG. 4, light passing through a plurality of regions 401 to 406 on the pupil plane 200 is incident on regions on the polarizing plate 135 which have the same reference numbers as those of the ranges on the pupil plane. Moreover, focal distances for the regions of the lens 110 that pass through light passing through region 401 on the pupil plane 200, light passing through region 403 on the pupil plane 200, and light passing through region 405 on the pupil plane 200 are different from those for the regions of the lens 110 that pass through light passing through region 402 on the pupil plane 200, light passing through region 404 on the pupil plane 200, and light passing through region 406 on the pupil plane 200.

As shown in the present drawing, light passing through the plurality of regions 401, 403, and 405 on the pupil plane passes through the polarizer 430a. Moreover, light passing through the plurality of regions 402, 404, and 406 on the pupil plane passes through the polarizer 430b.

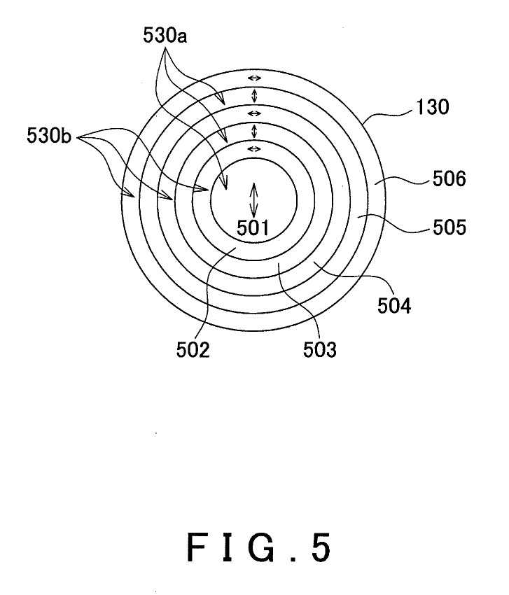

FIG. 5 shows further another configuration example of the polarizing plate 135. FIG. 5 shows a cross section, of the polarizing plate 135, perpendicular to the optical axis of the lens system 100.

A plurality of polarizers 530a (hereinafter, referred to as a polarizer 530a) and a plurality of polarizers 530b (hereinafter, referred to as a polarizer 530b) have shapes divided by a plurality of concentric border lines centered on a point intersecting with the optical axis. Moreover, the transmission axis of the polarizer 530a is perpendicular to the transmission axis of the polarizer 530b.

In addition, in FIG. 5, light passing through a plurality of regions 501 to 506 on the pupil plane 200 is incident on regions on the polarizing plate 135 which have the same reference numbers as those of the ranges on the pupil plane. Moreover, focal distances for the regions of the lens 110 that pass through light passing through region 501 on the pupil plane, light passing through region 503 on the pupil plane, and light passing through region 505 on the pupil plane are different from those for the regions of the lens 110 that pass through light passing through region 502 on the pupil plane, light passing through region 504 on the pupil plane, and light passing through region 506 on the pupil plane. As shown in the present drawing, light passing through the plurality of regions 501, 503, and 505 on the pupil plane passes through the polarizer 530a. Moreover, light passing through the plurality of regions 502, 504, and 506 on the pupil plane passes through the polarizer 530b.

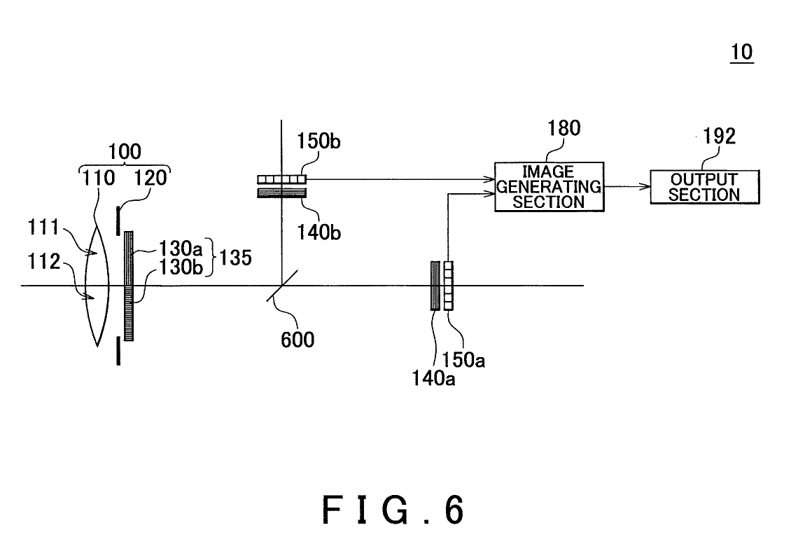

FIG. 6 shows another configuration example of the image capturing apparatus 10. The image capturing apparatus 10 includes a lens system 100 including a lens 110 and a diaphragm 120, a polarizing plate 135, an optical element 600, a plurality of analyzers 140a and 140b, and a plurality of light receiving element arrays 150a and 150b. In addition, since the lens system 100 and the polarizing plate 135 have substantially the same functions as those of the lens system 100 and the polarizing plate 135 shown in FIG. 1, their descriptions will be omitted. Moreover, since the analyzer 140a and the analyzer 140b are substantially the same as the analyzer 140a and the analyzer 140b shown in FIG. 1 except a function acting as a test plate, their descriptions will be omitted.

The optical element 600 forms an image by placing light transmitted through a first polarizer 130 that transmits light in a first polarization direction and light transmitted through a second polarizer 130 that transmits light in a second polarization direction at positions different from each other. For example, a half mirror can be used as the optical element 600.

The light receiving element array 150a has a plurality of light receiving elements that receive light transmitted through a polarizer 130a. The plurality of light receiving elements of the light receiving element array 150a are arranged in the vicinity of the imaging position of light transmitted through the polarizer 130a. The light receiving element array 150a is formed by arranging the plurality of light receiving elements in a matrix.

Moreover, the light receiving element array 150b has a plurality of light receiving elements that receive light transmitted through a polarizer 130b. The plurality of light receiving elements of the light receiving element array 150b are arranged in the vicinity of the imaging position of light transmitted through the polarizer 130b. The light receiving element array 150b is formed by arranging the plurality of light receiving elements in a matrix.

The image generating section 180 generates a first image by means of light received by the plurality of light receiving elements of the light receiving element array 150a, which receive light transmitted through the polarizer 130a. Moreover, the image generating section 180 generates a second image by means of light received by the plurality of light receiving elements of the light receiving element array 150b, which receive light transmitted through the polarizer 130b. According to this, it is possible to take in one shot a clear image for two subjects that are placed at different distances from the lens system 100.

Although some aspects of the present invention have been described by way of exemplary embodiments, it should be understood that those skilled in the art might make many changes and substitutions without departing from the spirit and the scope of the present invention which is defined only by the appended claims.

What is claimed is:

1. An image capturing device comprising:
a lens system including a plurality of regions on a pupil plane that each have different focal distances;
a plurality of first polarizing elements that respectively transmit differently polarized light and respectively transmit light passing through the plurality of regions;
a plurality of second polarizing elements that respectively transmit polarized light transmitted through the plurality of first polarizing elements; and
a plurality of light receiving elements that respectively receive light transmitted through the plurality of second polarizing elements.

2. The image capturing device according to claim 1, wherein
the plurality of first polarizing elements are a plurality of polarizers that transmit light polarized in different polarization directions and respectively transmit light passing through the plurality of regions,
the plurality of second polarizing elements are a plurality of analyzers that respectively transmit light which is polarized by the plurality of polarizers in the polarization directions of the plurality of polarizers, and
the plurality of light receiving elements respectively receive light transmitted through the plurality of analyzers.

3. The image capturing device according to claim 2, wherein the plurality of polarizers transmit light polarized in polarization directions substantially perpendicular to each other.

4. The image capturing device according to claim 3, wherein the plurality of polarizers are provided at a position closer to a subject than any focal points of the lens system.

5. The image capturing device according to claim 4, wherein the plurality of polarizers are provided on the pupil plane of the lens system.

6. The image capturing device according to claim 4, wherein the plurality of polarizers are provided at a position closer to the subject than to the lens system.

7. The image capturing device according to claim 5, wherein
the plurality of light receiving elements are arranged in a matrix, and
the plurality of analyzers are respectively arranged in a matrix in front of the plurality of light receiving elements.

8. The image capturing device according to claim 7, wherein the plurality of light receiving elements are provided between the plurality of focal points of the lens system.

9. The image capturing device according to claim 8, further comprising an image generating section that generates images by means of light having different polarization directions received by the plurality of light receiving elements.

10. The image capturing device according to claim 9, further comprising an output section that preferentially outputs as a captured image an image having the best picture quality among the plurality of images generated from the image generating section.

11. The image capturing device according to claim 9, further comprising an image combining section that generates a composite image made by combining the plurality of images generated from the image generating section.

12. The image capturing device according to claim 11, wherein the image combining section generates the composite image by providing a larger weight to an image having higher picture quality among the plurality of images generated from the image generating section and combining the images.

13. The image capturing device according to claim 7, wherein the plurality of fan-shaped regions in the lens system have different focal distances.

14. The image capturing device according to claim 7, wherein the plurality of regions divided by concentric circles in the lens system have different focal distances.

15. The image capturing device according to claim 7, further comprising an optical element that forms an image by placing at different positions light transmitted through a first polarizer that transmits light in a first polarization direction and light transmitted through a second polarizer that transmits light in a second polarization direction,
the plurality of light receiving elements that receive light transmitted through the first polarizer are arranged in the vicinity of an imaging position of light transmitted through the first polarizer, and
the plurality of light receiving elements that receive light transmitted through the second polarizer are arranged in the vicinity of an imaging position of light transmitted through the second polarizer.

16. The image capturing device according to claim 15, further comprising an image generating section that generates a first image by means of light received by the plurality of light receiving elements that receives light transmitted through the first polarizer and a second image by means of light received by the plurality of light receiving elements that receive light transmitted through the second polarizer.

17. The image capturing device according to claim 1, wherein the plurality of first polarizing elements respectively transmit polarized light substantially perpendicular to each other, which passes through the plurality of regions.

18. An optical system comprising:
a lens system including a plurality of regions on a pupil plane that each have different focal distances;
a plurality of first polarizing elements that respectively transmit differently polarized light and respectively transmit light passing through the plurality of regions; and
a plurality of second polarizing elements that respectively transmit polarized light transmitted through the plurality of first polarizing elements.
